(19) United States
(12) Patent Application Publication
(10) Pub. No.: US 2019/0226085 A1
(43) Pub. Date: Jul. 25, 2019

(54) SUBSTRATE SUPPORTING APPARATUS AND MANUFACTURING METHOD THEREOF

(71) Applicant: SANG GU PRECISION CO., LTD., Hwaseong-Si (KR)

(72) Inventors: Suk Chae JANG, Seoul (KR); Chan OH, Cheonan-Si (KR); Sung Ho PARK, Hanam-Si (KR); Sung Woon JUNG, Hanam-Si (KR); Sang Koo JANG, Seoul (KR); Il KIM, Hwaseong-Si (KR)

(21) Appl. No.: 16/240,688

(22) Filed: Jan. 4, 2019

(30) Foreign Application Priority Data
Jan. 22, 2018 (KR) 10-2018-0007876

(51) Int. Cl. C23C 16/458; C23C 14/54; C23C 14/50

(52) U.S. Cl. CPC C23C 16/4586; C23C 14/50; C23C 14/541

(57) ABSTRACT

Provided is a substrate supporting apparatus including: a mounting part provided with a first body brought into contact with a substrate so that the substrate is mounted thereon and a second body configured to surround the first body; and a support part connected under the mounting part so as to support the mounting part, wherein the first body and the second body include a plurality of protrusions, and an area of upper surfaces of the protrusions provided on the first body is formed larger than an area of upper surfaces of the protrusions provided on the second body, and thus, the substrate can be stably supported.

### CROSS-REFERENCE TO RELATED APPLICATION

This application claims priority to Korean Patent Application No. 10-2018-0007876 filed on Jan. 22, 2018 and all the benefits accruing therefrom under 35 U.S.C. § 119, the contents of which are incorporated by reference in their entirety.

### BACKGROUND

The present disclosure relates to a substrate supporting apparatus and a manufacturing method thereof, and more particularly, to a substrate supporting apparatus which allows the overall temperature of a substrate to be uniformly adjusted while stably supporting the substrate, and to a manufacturing method thereof.

In general, in order to manufacture products such as liquid crystal display devices and solar cells, various manufacturing processes, such as depositing various types of thin films on a substrate to be processed such as a glass substrate, and patterning the deposited thin film, are performed. Here, a process for forming a thin film on a substrate is performed by means of a deposition apparatus using a physical deposition method, or a deposition apparatus using a chemical deposition method.

The physical deposition method includes sputtering for making thin film particles directly collide with and adsorbed to a substrate. The chemical deposition method includes chemical vapor deposition for inducing a chemical reaction of radicals over a substrate and making the resultant thin film particles drop and adsorbed to the substrate.

A deposition apparatus for performing chemical vapor deposition may include a susceptor on which a substrate is mounted and a shower head for injecting a process gas from over the susceptor toward the substrate. In related arts, in order to stably mount a substrate on a susceptor, a shadow frame was provided along a peripheral surface of the susceptor. The shadow frame pressed an edge region of the substrate mounted on the susceptor to fix the substrate.

However, due to a separated space between the peripheral surface of the susceptor and the shadow frame, more heat loss occurred in a periphery than in a central portion of the susceptor. That is, due to a direct contact between the peripheral surface of the susceptor and the atmosphere, more heat loss occurred than in a central region. Thus, more heat loss occurred in a peripheral region adjacent to the periphery of the susceptor than in a central region of the substrate. Thus, there is a problem in that the overall temperature of the substrate becomes non-uniform.

In addition, since the degrees of thermal expansion and contraction of the susceptor and the shadow frame are different, particles may be generated due to friction between the susceptor and the shadow frame when processing the substrate. In addition, there is also a problem in that electrons are concentrated in a region at which the shadow frame presses the substrate, so that spark is generated on the substrate.

### RELATED ART DOCUMENTS

### Patent Documents

(Patent document 1) KR10-1628813 B

### SUMMARY

The present disclosure provides a substrate supporting apparatus capable of uniformly adjusting the overall temperature of a substrate and a manufacturing method thereof.

The present disclosure also provides a substrate supporting apparatus capable of preventing generation of particles and a manufacturing method thereof.

The present disclosure also provides a substrate supporting apparatus capable of suppressing or preventing the generation of spark on a substrate and a manufacturing method thereof.

In accordance with an exemplary embodiment, a substrate supporting apparatus includes: a mounting part provided with a first body brought into contact with a substrate so that the substrate is mounted thereon and a second body configured to surround the first body; and a support part connected under the mounting part so as to support the mounting part.

The first body and the second body may be provided with a plurality of protrusions, and an area of upper surfaces of the protrusions provided on the first body may be formed larger than an area of upper surfaces of the protrusions provided on the second body.

The second body may have a smaller surface roughness value than the first body.

An arithmetic average roughness value of the first body may be approximately 15-25 μm, and an arithmetic average roughness value of the second body may be approximately 1.6-3.6 μm.

The substrate supporting apparatus may further include a heating part installed on the mounting part so as to heat the substrate mounted on the mounting part.

A vertical direction thickness of the first body may be larger than the vertical direction thickness of the second body, and

The heating part may be installed only on the first body.

The vertical direction thickness of the first body may be formed no greater than the vertical direction thickness of the second body, and

The heating part may be installed on the first body and the second body.

The substrate supporting apparatus may further include a protrusion part protruding upward from a surface of the second body and installed so as to surround at least a portion of a periphery of the substrate.

The protrusion part may include a heating member so as to heat an edge area of the substrate.

An insertion groove may be provided in the second body, and the mounting part may include an engagement member detachably installed in the insertion hole so as to engage with a transporting apparatus for transporting the substrate supporting apparatus.

The mounting part may include an insertion member detachably installed into the insertion groove from which the engagement member has been detached.

A separation space may be provided between at least a portion of the insertion groove and the insertion member.

In accordance with another exemplary embodiment, a method for manufacturing a substrate supporting apparatus for supporting a substrate, the method including: providing a mounting part including a first region brought into contact with a substrate and a second region configured to surround a second region; and processing a surface of the first region and processing a surface of the second region so that a surface roughness value of the second region is smaller than that of the first region.

The processing of the surface of the first region may include processing so as to increase a contact area between the first region and the substrate.

The processing of the surfaces of the first region and the second region may include: coating a surface of one region among the first region and the second region with a coating agent and injecting particles on other regions; removing the coating agent from the one region and coating surfaces of the other regions with another coating agent; injecting particles on the surface of the one region; and removing the coating agent from the other regions.

The processing of the surfaces of the first region and the second region may include injecting onto the second region particles having smaller diameters than those of the particles injected onto the first region.

The method for manufacturing a substrate supporting apparatus may further include, after the processing of the surfaces of the first region and the second region, installing the substrate supporting apparatus inside a chamber.

The providing of the mounting part may include forming an insertion hole in a periphery of the mounting part;

and the installing the substrate support apparatus inside a chamber may include: installing an engagement member into the insertion groove and making the engagement member engage with a transporting apparatus; and positioning the substrate supporting apparatus inside the chamber by means of the transporting apparatus.

The installing the substrate support apparatus inside a chamber may include: separating the engagement member from the insertion groove; and filling the inserting groove.

### BRIEF DESCRIPTION OF THE DRAWINGS

Exemplary embodiments can be understood in more detail from the following description taken in conjunction with the accompanying drawings, in which:

FIG. 1 is a view illustrating a structure of substrate processing equipment in accordance with an exemplary embodiment;

FIG. 2 is a view illustrating a structure of a substrate supporting apparatus in accordance with an exemplary embodiment;

FIG. 3 is a schematic view illustrating shapes of protrusions of a first body and a second body in accordance with an exemplary embodiment;

FIG. 4 is a view for comparing the thicknesses of a first body and a second body in accordance with an exemplary embodiment;

FIG. 5 is a view illustrating a structure in which an engagement member is installed on a second body in accordance with an exemplary embodiment;

FIG. 6 is a view illustrating a structure in which an insertion member is installed on a second body in accordance with an exemplary embodiment;

FIG. 7 is a view illustrating a structure of a substrate supporting apparatus in accordance with another exemplary embodiment; and

FIG. 8 is a flowchart illustrating a method for manufacturing a substrate supporting apparatus in accordance with an exemplary embodiment.

### DETAILED DESCRIPTION OF EMBODIMENTS

Hereinafter, exemplary embodiments will be described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The drawings may be exaggerated to describe the present disclosure in detail, and like reference numerals refer to like elements in the drawings.

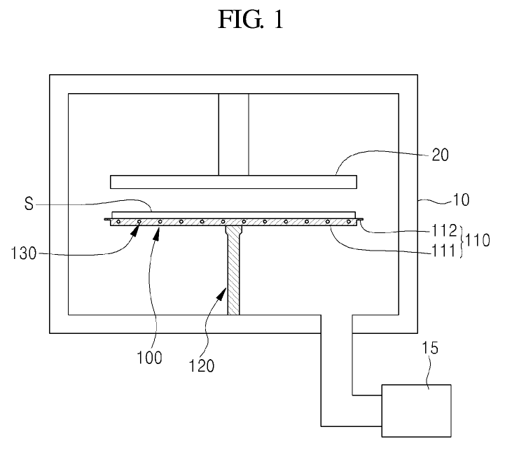

FIG. 1 is a view illustrating a structure of substrate processing equipment in accordance with an exemplary embodiment. Hereinafter in order to understand exemplary embodiments, a structure of substrate processing equipment according to an exemplary embodiment will be described.

Referring to FIG. 1, the substrate processing equipment includes a chamber 10, an injection apparatus 20, and a substrate supporting apparatus 100. Here, the substrate processing equipment may perform a process for forming a thin film on a substrate S, and the substrate may be a glass substrate.

The chamber 10 is formed in a box shape. The chamber 10 has an inner space. On one side of the chamber 10, provided is an entrance opening (not shown) through which the substrate S may be loaded/unloaded. A gate valve may be installed on the entrance opening. A transfer part (not shown) for transferring the substrate S may be installed in the chamber 10. Accordingly, the substrate S may be transferred into the chamber 10 and a process for processing the substrate S may be performed.

In addition, a pressure pump 15 may be connected to the chamber 10. Accordingly, the pressure inside the chamber 10 may be controlled by means of the pressure pump 15. However, the structure and shape of the chamber 10 is not limited thereto but may be diversified.

The substrate supporting apparatus 100 supports the substrate S inside the chamber 10. At least a portion of the substrate supporting apparatus 100 is located on a lower portion inside the chamber 10. The substrate S may be mounted on the upper surface of the stage 100.

The injection apparatus 20 may supply a raw material to be deposited onto the substrate S. The injection apparatus 20 is located on an upper portion inside the chamber 10. The injection apparatus 20 is disposed to face the substrate supporting apparatus 100, and the injection apparatus 20 and the substrate supporting apparatus 100 are vertically spaced apart from each other.

For example, the injection apparatus 20 may be formed in a shower head-shape. Accordingly, the injection apparatus 20 may inject the raw materials supplied from the outside onto the upper surface of the substrate S. Accordingly, the raw materials may be deposited onto the substrate S and form a thin film. However, the structure of the injection apparatus 20 and a method for depositing raw materials onto the substrate S are not limited thereto, but may be diversified.

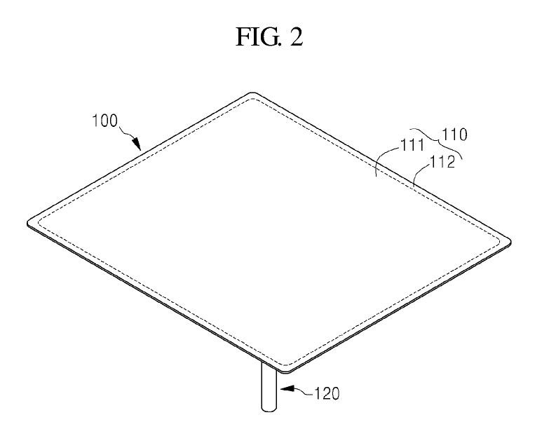

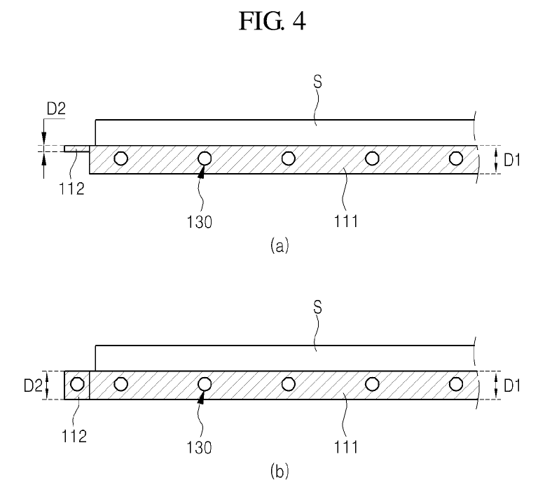

FIG. 2 is a view illustrating a structure of a substrate supporting apparatus in accordance with an exemplary embodiment, FIG. 2 is a schematic view illustrating shapes of protrusions of a first body and a second body in accordance with an exemplary embodiment, and FIG. 4 is a view comparing the thicknesses of a first body and a second body in accordance with an exemplary embodiment. Hereinafter the structure of the substrate supporting apparatus according to exemplary embodiments will be described in more detail.

Referring to FIGS. 1 and 2, a substrate supporting apparatus 100 is an apparatus for supporting a substrate S. The substrate supporting apparatus 100 includes a mounting part 110 and a support part 120. In addition, the substrate supporting apparatus 100 may further include a heating part 130. At this point, the substrate supporting apparatus 100 is provided to substrate processing equipment and may support the substrate S while performing a process for processing the substrate S.

The support part 120 is connected to a lower portion of the mounting part 110. Accordingly, the support part 120 may support the mounting part 110. The support part 120 includes a shaft. In addition, the support part 120 may further include a vertical drive device (not shown) and rotation drive device (not shown).

The shaft may extend in the vertical direction. The upper end portion of the shaft is connected to the lower surface of the mounting part 110. The lower end portion of the shaft may be fixed to the bottom surface of the chamber 10. Alternatively, the lower end portion of the shaft may also pass through the bottom of the chamber 10 and be located outside the chamber 10.

The vertical drive device is connected to the shaft. For example, the vertical drive device may be a cylinder, and may move the shaft up and down. Accordingly, the mounting part 110 connected to the shaft may vertically move. Thus, the distance between the substrate S mounted on the upper surface of the mounting part 110 and the injection apparatus 20 may be adjusted. However, methods in which the vertical drive device vertically moves the shaft are not limited thereto, but may be diversified.

The rotation drive device is connected to the shaft. For example, the rotation drive device may be a motor, and may rotate the shaft around the vertical center axis of the shaft. Accordingly, the mounting part 110 connected to the shaft may rotate around the shaft. Thus, while rotating the substrate S mounted on the upper surface of the mounting part 110, raw materials may be supplied onto the substrate by means of the injection apparatus 20. However, methods in which the rotation drive device rotates the shaft are not limited thereto, but may be diversified.

The heating part 130 is installed in the mounting part 110. The heating part 130 may heat the substrate S mounted on the mounting part 110. For example, the heating part 130 may be provided with a coil or heating wire which generates heat. The heating part 130 may be disposed according to the shape of the substrate S or the mounting part 110. The heating part 130 may be installed under the mounting part 110 or installed so as to be inserted into the mounting part 110. Accordingly, heat generated from the heating part 130 may be transferred to the substrate S via the mounting part 110. However, the structure of the mounting part 110 and a method for generating heat are not limited thereto but may be diversified.

The mounting part 110 is disposed inside the chamber, and may be formed in a plate shape. For example, the mounting part 110 may be formed corresponding to the shape of the substrate S. Accordingly, when the substrate S is rectangular, the mounting part 110 may also be formed in a rectangular shape, and when the substrate S is circular, the mounting part 110 may also be formed in a circular shape. Thus, the substrate S may stable be mounted and supported on the upper surface of the mounting part 110. The mounting part 110 includes a first body 111 and a second body 112.

The first body 111 is a region which may contact the substrate S on the mounting part 110. The first body 111 may be formed corresponding to the shape of the substrate S. The area of the first body 111 may be formed in an area larger than or equal to the area of the substrate S. Accordingly, the entirety of the lower surface of the substrate S may contact the first body 111.

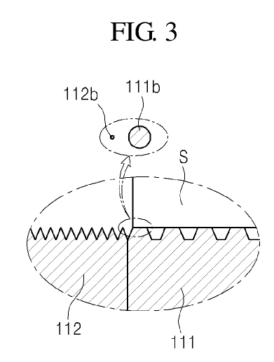

In addition, as shown in FIG. 3, the surface (or the upper surface) of the first body 111 is provided with a plurality of protrusions which may contact the substrate S. That is, since the surface of the first body 111 has a surface roughness, the plurality of protrusions may be formed on the surface of the first body 111. The area of the upper surfaces of the protrusions 111b provided on the first body 111 may be formed larger than the area of the upper surfaces of protrusions 112b provided on the second body 112.

At this point, the total area of the upper surfaces of the protrusions 111b provided on the first body 111 are larger than the total area of the upper surface of protrusions 112b provided on the second body 112. In addition, the area of the upper surface of one protrusion 111b provided on the first body 111 is larger than the area of the upper surface of one protrusion 112b provided on the second body 112.

For example, the cross-sectional shapes of the protrusions on the first body 111 may each be formed in a trapezoidal shape, and the cross-sectional shapes of the protrusions on the second body 112 may each be formed in a triangular shape. Accordingly, an area by which the substrate S and the protrusions of the first body 111 may contact may increase, and the magnitude of friction force generated between the substrate S and the first body 111 may be increased. Thus, the substrate S may stably be mounted on the first body 111 without slip.

In addition, since the area, which actually contacts the substrate S, may be increased in the first body 111, a separate shadow frame for fixing the substrate S may not be provided. That is, since the substrate S is stably supported on the protrusions of the first body 111 and the occurrence of slip may be prevented, the substrate S may stably be positioned on the first body 111 even without a shadow frame. Thus, particles may be prevented from being generated due to friction between the mounting part 110 and the shadow frame.

At this point, the arithmetic average roughness value of the surface of the first body 111 may be approximately 15 μm to approximately 25 μm. When the arithmetic average roughness value of the first body 111 is less than approximately 15 μm, the area of the upper surfaces of the protrusions of the first body 111 is not easily increased, and thus, the substrate S on the protrusions may easily slide. Accordingly, the substrate S may not be stably supported on the mounting part 110, and thus, a process for processing the substrate S may not be performed stably.

Conversely, when the arithmetic average roughness value of the first body 111 is greater than approximately 25 μm, friction is caused between the substrate S and the first body 111, and thus, the amount of generated particles may increase. Thus, in order to reduce the amount of generated particles while stably supporting the substrate S, the average surface roughness value of the first body 111 may be adjusted.

Referring to FIG. 2, the second body 112 is a region which surrounds the periphery of the first body 111 in the mounting part 110. The second body 112 may be formed along the peripheral shape of the first body 111. The second body 112 may not contact the substrate S. Accordingly, the second body 112 may be spaced apart from the substrate S. The first body 111 and the second body 112 may be integrally manufactured, or may also be separately manufactured and assembled.

In this case, the separation distance between the peripheral surface of the mounting part 110 and the substrate S may be increased by means of the second body 112. That is, the larger the outer diameter or size of the second body 112, the further the separation distance between the peripheral surface, where much heat loss occurs, of the mounting part 110 and a peripheral region the substrate S may be increased. Accordingly, heat loss caused more in the edge region of the substrate S than in the central region may be suppressed or prevented. Thus, the overall temperature of the substrate S may easily be adjusted uniformly.

As shown in FIG. 3, the plurality of protrusions are provided on the surface (or the upper surface) of the second body 112. That is, since the surface of the second body 112 has a surface roughness, the plurality of protrusions may be formed on the surface of the second body 112. The area of the upper surfaces of the protrusions provided on the second body 112 may be formed smaller than the area of the upper surfaces of the protrusions provided on the first body 111. Accordingly, the upper surfaces of the protrusions of the second body 112 may be formed sharper than the upper surfaces of the protrusions of the first body 111.

In addition, since the protrusions provided on the second body 112 are formed sharp, the protrusions may function as a lightning rod. Thus, when spark occurs in the mounting part 110, the spark may be guided to the second body 112. Accordingly, spark is guided to occur in the second body 112 spaced apart from the substrate S, so that the occurrence of spark toward the substrate S on the first body 111 may be suppressed or prevented.

At this point, the arithmetic average roughness value of the surface of the second body 112 may be approximately 1.6 μm to approximately 3.6 μm. When the arithmetic average roughness value of the second body 112 is less than approximately 1.6 μm, spark may not be guided to the second body 112. That is, the distance between the protrusions of the second body 112 becomes too small, the upper surface of the second body 112 may be formed flat, and the protrusions may not function as a lightning rod. Thus, spark is guided toward the first body 111 and may damage the substrate S.

Conversely, when the arithmetic average roughness value of the second body 112 is larger than approximately 3.6 μm, the amount of generated particles may increase in the second body 112. Thus, in order to reduce the amount of generated particles while guiding spark toward the second body 112, the average surface roughness value of the second body 112 may be adjusted. The arithmetic average roughness value may be a roughness value which is obtained, from a roughness curve of the first body 111 or the second body 112, after moving the curve under the average line to over the average line.

At this point, the roughness of the surface of the second body 112 may vary for each region. For example, the surface of the second body 112 may be divided into an inner surface enclosing the periphery of the first body 111 and an outer surface enclosing the periphery of the inner surface. The surface roughness of the outer surface may be larger than that of the inner surface. Accordingly, spark may be induced to the outer surface of the second body 112, and the outer surface and the first body 111 may be spaced apart from each other by the inner surface. Thus, by increasing the spacing distance between the substrate S on the first body 111 and the region to which spark is induced, spark can be effectively suppressed or prevented from being generated.

Meanwhile, referring to (a) of FIG. 4, the vertical direction thickness D1 of the first body 111 may be larger than the vertical direction thickness D2 of the second body 112. That is, the upper surfaces of the first body 111 and the second body 112 are located at the same height, and the first body 11 may further protrude downward than the second body 112.

At this point, the heating part 130 may be installed only to the first body 111. Since the thickness of the second body 112 is smaller than the thickness of the first body 111, heat generated from the heating part 130 may easily be transferred up to the second body 112. Accordingly, heat loss caused more in the edge region of the substrate S may be suppressed or prevented. Thus, the overall temperature of the substrate S may easily be controlled uniformly.

Alternatively, as shown in (b) of FIG. 4, the vertical direction thickness D1 of the first body 111 may also be formed equal to the vertical direction thickness D2 of the second body 112. That is, all the upper surfaces and the lower surfaces of the first body 111 and the second body 112 may be positioned at the same height. Alternatively, the vertical direction thickness D1 of the first body 111 may also be formed smaller than the vertical direction thickness D2 of the second body 112. In this case, the heating part 130 may be installed both in the first body 111 and the second body 112. Since the thickness of the second body 112 is at least the thickness of the first body 112, when the heating part 130 is installed only in the first body 111, the temperature of the second body 112 may not easily be raised. Accordingly, heat loss occurs in the second body 112, and heat loss also occurs in the edge region of the substrate S adjacent to the second body 112. Thus, the heating part 130 is also installed in the second body 112, so that the occurrence of heat loss in the edge region of the substrate S may be suppressed or prevented in the second body 112.

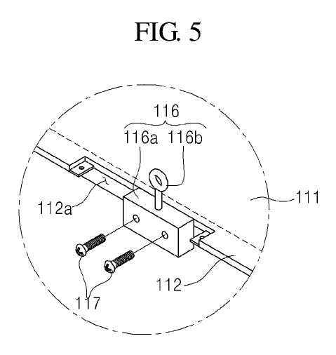

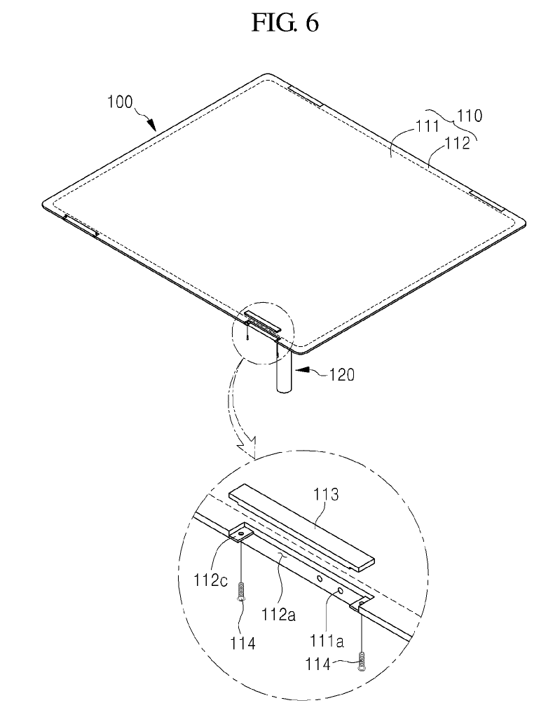

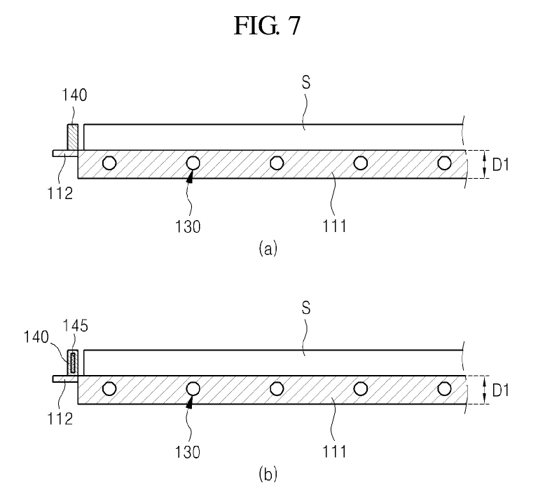

FIG. 5 is a view illustrating a structure in which an engagement member is installed on a second body in accordance with an exemplary embodiment, FIG. 6 is a view illustrating a structure in which an insertion member is installed on a second body in accordance with an exemplary embodiment, and FIG. 7 is a view illustrating a structure of a substrate supporting apparatus in accordance with another exemplary embodiment. Hereinafter, a structure in accordance with an exemplary embodiment in which an engagement member or an insertion member is installed in an insertion groove, and a structure of a substrate supporting apparatus in accordance with another exemplary embodiment will be described.

Referring to FIG. 5, an insertion groove 112a may also be formed in the second body 112. The insertion groove 112a may be formed in a shape recessed inward from the outer surface (or peripheral surface) of the second body 112. For example, the insertion groove 112a may be provided in plurality and may be disposed along the periphery of the second body 112.

In addition, the mounting part 110 may further include an engagement member 116. The engagement member 116 may be installed in the insertion hole 112a. The engagement member 116 may be detachably installed in the insertion groove so that a transportation apparatus (not shown) capable of transporting the substrate supporting apparatus 100 may engage therewith. The plurality of engagement members 116 as much as the number, by which the insertion holes 112a are provided, may be provided. The engagement members 116 may each include a frame 116a and an eye bolt 116b. The frame 116a may be coupled to a side surface of the first body 111 inside the insertion hole 112a. First fastening bolts 117 may pass through the frame 116a and be fastened to fastening holes 111a formed in the side surface of the first body 111. The frame 116a may be fixed in or detached from the insertion groove 112a by means of the first fastening bolts 117.

Meanwhile, a magnetic members (not shown) may be provided instead of the first fastening bolts 117. The magnetic member may include an electromagnet and be installed on the engagement member 116. At least a portion of the wall defining the insertion holes 112a of the second body 112 may be formed of a metal material. Thus, when power is supplied to the magnetic member to generate magnetic force, the magnetic member is attached to the wall of the second body 112 and the engagement member 116 may be coupled to the second body 112. When power supply to the magnetic members is stopped, the magnetic member may be separated and the engagement member 116 may be also separated from the second body 112. Accordingly, the engagement member 116 may be more easily attached to or separated from the second body 112.

The lower end portion of the eye bolt 116b is fastened to an upper portion of the frame 116a, and the upper portion may be formed in a shape of a circular ring or a hook. A hook of a crane or the like may engage with an upper end portion of the eye bolt 116b. Accordingly, the substrate supporting apparatus 100 may easily be moved by using a transportation apparatus (not shown) such as a crane. However, the structure and shape of the engagement member 116 are not limited thereto but may be diversified.

As shown in FIG. 6, the insertion groove 112a may include a first groove and a second groove. The first groove is located higher than the second groove, and the width of the first groove may be formed larger than the width of the second groove. Accordingly, a height difference may be formed between the first groove and the second groove. An insertion member 113 or an engagement member 116 may be assembled and installed in the insertion groove 112a. However, the structure and shape of the insertion groove 112a are not limited thereto but may be diversified.

The insertion member 113 may be detachably installed in the insertion groove 112a from which the engagement member 112 has been separated. The plurality of insertion members 113 as much as the number, by which the insertion holes 112a are provided, may be provided. The insertion member 113 may be formed corresponding to the shape of the insertion groove 112a. Accordingly, the insertion member 113 may fill a free space formed by the insertion groove 112a. Thus, the insertion member 113 may prevent the peripheral region of the mounting part 110 and the edge region of the substrate S from being adjacent to each other by using the portion at which the insertion groove 112a is formed in the mounting part 110. The overall temperature of the substrate S may be uniformly controlled by means of the second body 112 and the insertion member 113.

In addition, the width of the upper portion of the insertion member 113 may be formed larger than the width of the lower portion. The width of the upper portion of the insertion member 113 is formed in a size no greater than the width of the first groove, and larger than the width of the second groove. The width of the lower portion of the insertion member 113 is formed in a size no greater than the width of the second groove. Accordingly, the insertion member 113 may be mounted on a step 112c between the first groove and the second groove. At this point, second fastening bolts 114 may pass through the step 112c between the first groove and the second groove and be fastened to an upper portion of the insertion member 113. The insertion member 113 may be fixed in or detached from the insertion groove 112a by means of the second fastening bolts 114.

The insertion member 113 may be formed of a material containing ceramic. At this point, a separation space may be formed between at least a portion of the insertion groove 112a and the insertion member 113. That is, clearances may be present between the upper portion of the insertion member 113 and the first groove, and between the lower portion of the insertion member 113 and the second groove. Since the materials of the insertion member 113 and the second body 112 are different, the thermal expansion coefficients of the insertion member 113 and the second body 112 may be different. Since the clearance is present between the insertion member 113 and the second body 112, the insertion member 113 or the second body 112 may be prevented from being damaged while subjected to thermal expansion. However, the structure and material of the insertion member 113 are not limited thereto but may be diversified.

Thus, when performing a process for processing the substrate S, the insertion member 113 may be installed in the insertion groove 112a, and when performing a work for moving the substrate supporting apparatus 100, the engagement member 116 may be installed in the insertion groove 112a. The substrate supporting apparatus 100 may be transported when installed in substrate processing equipment or when a work for repairing the inside of the substrate processing equipment is performed.

Meanwhile, referring to (a) of FIG. 7, a substrate supporting apparatus 100 may further include a protrusion part 140. The protrusion part 140 may protrude upward from a surface of a second body 112. For example, the protrusion part 140 may be located on the second body 112 to face a border line connected to a first body 111.

In addition, the protrusion part 140 may be installed so as to surround a portion of the periphery of a substrate S. For example, the protrusion part 140 may be formed in a rectangular ring shape or a circular ring shape corresponding to the peripheral shape of the substrate S. Alternatively, the protrusion part may also be formed in a shape in which a plurality of partitions are disposed along the periphery of the substrate S. Accordingly, the protrusion part 140 may prevent the substrate S from sliding on the first body 111 and entering the second body 112. Thus, the substrate S may be maintained in a state of being stably mounted on the first body 111.

At this point, as shown (b) of FIG. 7, a heating member 145 may also be installed in the protrusion part 140. The heating member 145 may be a heating wire. The heating member 145 may be installed inside the protrusion part or installed on a surface of the protrusion part 140 which may face the substrate S. Thus, the heating member 145 may heat the edge region, of the substrate S, facing the protrusion part 140. Accordingly, a drop in temperature in the edge region of the substrate S may effectively be prevented, and the temperature of the substrate S may easily be adjusted. The heating member 145 may generate thermal energy at the same temperature as the heating part 130. However, embodiments are not limited thereto, but various combinations may be possible between embodiments.

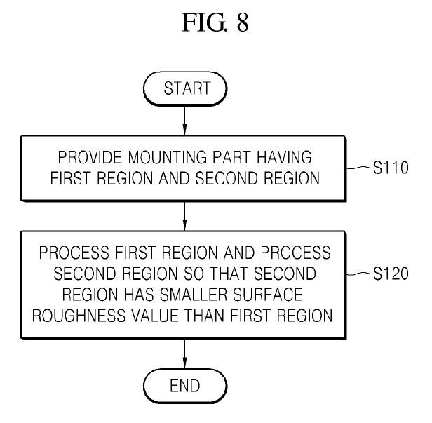

FIG. 8 is a flowchart illustrating a method for manufacturing a substrate supporting apparatus in accordance with an exemplary embodiment. Hereinafter a method for manufacturing a substrate supporting apparatus in accordance with an exemplary embodiment will be described.

Referring to FIG. 8, a method for manufacturing a substrate supporting apparatus includes: providing a mounting part provided with a first region brought into contact with a substrate and a second region configured to surround a second region (S110); and processing a surface of the first region and processing a surface of the second region so that the surface roughness value of the second region is smaller than that of the first region (S120). Here, the first region may be the upper surface of a first body provided to a mounting part, and the second region may be the upper surface of a second body provided to a mounting part. That is, the first region may be a region contacting the substrate mounted on the mounting part, and the second region may be a region spaced apart from the substrate mounted on the mounting part. In addition, the surface roughness value may be a roughness value.

Firstly, referring to FIGS. 1 to 3, a mounting part 110 formed in a plate shape may be provided. The upper surface of the mounting part 110 has a first region on which a substrate is mounted and a second region which surrounds the periphery of the first region.

Next, an operation of processing the surface of the first region and the surface of the second region so that the surface roughness values of the surface of the first region and the surface of the second region become different from each other. An exemplary embodiment exemplarily describes that the surface of the first region is firstly processed and the surface of the second region is subsequently processed. However, embodiments are not limited thereto, but the surface of the first region may be processed after the surface of the second region is processed.

Before processing the surface of the first region, the surface of the second region may be coated with a coating agent. For example, a masking agent is applied only to the surface of the second region, so that only the surface of the second region may be coated.

When the surface of the second region is coated with the coating agent, particles mat be injected to the surface of the first region which has not been coated with the coating agent. For example, the surface of the first region may be polished through a sand blasting method. Grid glass balls, silica sand, marine sand, and the like which have small diameters may be used for particles or polishing agents. Since the coating agent protects the surface of the second region, the surface of the second region may not be processed by the particles injected to the first region. However, the types of the particles are not limited thereto and may be diversified.

At this point, the arithmetic average roughness value of the surface of the first region may be approximately 15 μm to approximately 25 μm. When the arithmetic average roughness value of the surface of the first region is less than 15 μm, the contact area between the substrate S and the first region decreases and the substrate S may slide. Accordingly, the substrate S may not be stably supported on the mounting part 110, and thus, a process for processing the substrate S may not be stably performed.

Conversely, when the arithmetic average roughness value of the first region is greater than approximately 25 μm, friction is caused between the substrate S and the first region, and thus, the amount of generated particles may increase. Thus, in order to reduce the amount of generated particles while stably supporting the substrate S, the average surface roughness value of the first region may be adjusted.

Meanwhile, in order to increase a contact area between the first region and the substrate S, an operation of processing the first region may also further be performed. For example, a post-processing such as peeling may be performed on the surface of the first region. When the surface of the first region is peeled, the upper end portions of protrusions formed in the first region may be flattened. Thus, a contact area between the protrusions of the first region and the substrate S increases, so that the position of the substrate may be stably fixed. Accordingly, even without providing a separate shadow frame for fixing the substrate S, the substrate S may be stably supported on the surface of the first region due to the roughness value of the first region, and problems occurring when providing a shadow frame may be prevented.

Subsequently, the coating agent is removed from the second region, and the surface of the first region polished by particles may be coated with a coating agent. For example, a masking agent is applied only to the surface of the first region, so that only the surface of the first region may be coated. However embodiments are not limited thereto, but the coating agent may be removed from the second region after coating the first region with a coating agent, or the operations of removing the coating agent from the second region and coating the first region may also be performed simultaneously.

When the surface of the first region is coated with the coating agent, particles may be injected to the surface of the second region from which the coating agent has been removed. For example, the surface of the second region may be polished through a sand blasting method. Grid glass balls, silica sand, marine sand, and the like which have small diameters may be used for particles or polishing agents. Since the coating agent protects the surface of the first region, the surface of the first region may not be processed by the particles injected to the second region. However, the types of the particles are not limited thereto and may be diversified.

At this point, the average diameter of the particles injected to the second region may be smaller than the average diameter of the particles injected to the first region. Thus, the surface roughness value of the second region may be smaller than the surface roughness value of the first region. A plurality of protrusions are formed on the surfaces of the first region and the second region by the particles injected. Since the surface roughness value of the second region is small, the protrusions formed in the second region are disposed in a concentrated form compared to the protrusions formed in the first region.

In addition, the protrusions formed in the second region do not pass through a separate flattening process, and may thereby be formed in sharp shapes. Accordingly, since the protrusions in the second region may function as a lightning rod, when spark occurs in the mounting part 110, the spark may be guided to the second region. It is possible to suppress or prevent the occurrence of spark in the substrate S on the first region.

At this point, the arithmetic average roughness value of the surface of the second region may be approximately 1.6 μm to approximately 3.6 μm. When the arithmetic average roughness value of the second region is less than approximately 1.6 μm, spark may not be guided to the second region. That is, the distance between the protrusions in the second region becomes too small, the surface of the second region may be formed flat overall, and the protrusions may not function as a lightning rod. Thus, spark is guided to the substrate S on the first region and may damage the substrate S.

Conversely, when the arithmetic average roughness value of the second region is larger than approximately 3.6 μm, the amount of generated particles may increase in the second region. Thus, in order to reduce the amount of generated particles while guiding the spark to the second region, the average roughness value of the second region may be adjusted.

The second region is a region surrounding the periphery of the first region. Thus, the separation distance between the peripheral surface of the mounting part 110 and the substrate S may be increased due to the second region. That is, the larger the outer diameter or size of the second region, the further the separation distance between the peripheral surface, where much heat loss occurs, of the mounting part 110 and an edge region of the substrate S may be increased. Accordingly, it is possible to suppress or prevent the phenomenon that more heat loss occurs in the peripheral region of the substrate S than in the central portion, and thus, the overall temperature of the substrate S may be uniformly adjusted.

Next, the coating agent may be removed from the first region coated with the coating agent. Thus, the first region and the second region may be processed so as to have different surface roughness values from each other. In addition, the surface of the first region is post-processed, so that the protrusions in the first region and the protrusions in the second region may be formed in different shapes from each other.

Next, the substrate supporting apparatus 100 may be installed inside a chamber 10. At this point, referring to FIGS. 5 and 6, insertion grooves 112a may be formed in the periphery of the mounting part 110. That is, the mounting part 110 in which the insertion grooves 112a are formed may be provided. The insertion grooves 112a may be formed in a shape recessed inward from the peripheral surface of the mounting part 110.

Next, an engagement member 116 may be installed in each of the insertion grooves 112a. The engagement member 116 is provided with an eye bolt 116b. The eye bolts 116b of the engagement member 116 may be directly or indirectly connected to a transporting apparatus. Thus, while connected to the engagement member 116, the transporting apparatus (not shown) may transport the substrate supporting apparatus 100. Accordingly, the substrate supporting apparatus 100 may be installed inside the chamber 10 by controlling the operation of the transporting apparatus.

Next, the engagement member 116 installed in the insertion groove 112a may be detached. The insertion groove 112a from which the engagement member 116 has been detached may be filled. For example, an insertion member 113 formed corresponding to the shape of the insertion groove 112a may be provided and the insertion member 113 may be installed in the insertion groove 112a. The insertion member 113 may fill a free space formed by the insertion groove 112a. Thus, the insertion member 113 may prevent the peripheral region of the mounting part 110 and the edge region of the substrate S from being adjacent to each other by using the portion at which the insertion groove 112a is formed in the mounting part 110.

As such, an upper surface of a substrate supporting apparatus is processed, so that even without providing a shadow frame, a substrate may be stably mounted in a mounting part. Accordingly, particles may be prevented from being generated due to friction between the mounting part and the shadow frame.

In addition, a second region surrounding the periphery of a first region is provided, so that the separation distance between the peripheral surface of the mounting part and the substrate may be increased. That is, in the mounting part, the separation distance between a peripheral region at which much heat loss occurs and an edge region of the substrate may be increased. Accordingly, heat loss caused more in the edge region of the substrate than in the central region may be suppressed or prevented. Thus, the overall temperature of the substrate may easily be adjusted uniformly.

In addition, on the upper surface of the mounting part, the roughness value of a region separated from the substrate may be provided smaller than the roughness value of a region on which the substrate is mounted. Thus, spark may be guided to occur in the region separated from the substrate, so that the spark may be prevented from occurring on the substrate.

According to exemplary embodiments, a substrate may be stably mounted on a mounting part without providing a shadow frame. Thus, particles may be prevented from being generated due to friction between the mounting part and the shadow frame.

In addition, the separation distance between the peripheral surface of the mounting part and the substrate may be increased. That is, in the mounting part, the separation distance between a peripheral region at which much heat loss occurs and a peripheral region of the substrate may be increased. Accordingly, heat loss caused more in the peripheral region of the substrate than in the central region may be suppressed or prevented. Thus, the overall temperature of the substrate may easily be adjusted.

In addition, on the upper surface of the mounting part, the roughness value of a region separated from the substrate may be provided smaller than the roughness value of a region on which the substrate is mounted. Thus, spark may be guided to occur in the region, of the mounting part, separated from the substrate, so that the spark may be prevented from occurring on the substrate.

So far, in the detailed description of the present disclosure, specific exemplary embodiments have been described, but various modifications can be made thereto without departing from the spirit and scope of the present disclosure. Therefore, the scope of the invention is defined not by the detailed description of the invention but by the appended claims, and all differences within the scope will be construed as being included in the present invention.

What is claimed is:

1. A substrate supporting apparatus comprising:
a mounting part comprising a first body brought into contact with a substrate so that the substrate is mounted thereon and a second body configured to surround the first body; and
a support part connected under the mounting part so as to support the mounting part, wherein
the first body and the second body comprise a plurality of protrusions, and an area of upper surfaces of the protrusions provided on the first body is formed larger than an area of upper surfaces of the protrusions provided on the second body.

2. The substrate supporting apparatus of claim 1, wherein the second body has a smaller surface roughness value than the first body.

3. The substrate supporting apparatus of claim 2, wherein
an arithmetic average roughness value of the first body is approximately 15-25 μm, and
an arithmetic average roughness value of the second body is approximately 1.6-3.6 μm.

4. The substrate supporting apparatus of claim 1, further comprising a heating part installed on the mounting part so as to heat the substrate mounted on the mounting part.

5. The substrate supporting apparatus of claim 4, wherein
a vertical direction thickness of the first body is larger than a vertical direction thickness of the second body, and
the heating is installed only on the first body.

6. The substrate supporting apparatus of claim 4, wherein
the vertical direction thickness of the first body is formed no greater than the vertical direction thickness of the second body, and
the heating part is installed on the first body and the second body.

7. The substrate supporting apparatus of claim 4, further comprising a protrusion part protruding upward from a surface of the second body and installed so as to surround at least a portion of a periphery of the substrate.

8. The substrate supporting apparatus of claim 7, wherein the protrusion part comprises a heating member so as to heat an edge area of the substrate.

9. The substrate supporting apparatus of claim 1, wherein
an insertion groove is provided in the second body, and
the mounting part comprises an engagement member detachably installed in the insertion hole so as to engage with a transporting apparatus for transporting the substrate supporting apparatus.

10. The substrate supporting apparatus of claim 9, wherein the mounting part comprises an insertion member detachably installed into the insertion groove from which the engagement member has been detached.

11. The substrate supporting apparatus of claim 10, wherein a separation space is provided between at least a portion of the insertion groove and the insertion member.

12. A method for manufacturing a substrate supporting apparatus for supporting a substrate, the method comprising:
providing a mounting part comprising a first region brought into contact with a substrate and a second region configured to surround a second region; and
processing a surface of the first region and processing a surface of the second region so that a surface roughness value of the second region is smaller than that of the first region.

13. The method of claim 12, wherein the processing of the surface of the first region comprises processing so as to increase a contact area between the first region and the substrate.

14. The method of claim 12, wherein the processing of the surfaces of the first region and the second region comprises:
coating a surface of one region among the first region and the second region with a coating agent and injecting particles on other regions;
removing the coating agent from the one region and coating surfaces of the other regions with another coating agent;
injecting particles on the surface of the one region; and
removing the coating agent from the other regions.

15. The method of claim 14, wherein the processing of the surfaces of the first region and the second region comprises injecting onto the second region particles having smaller diameters than those of the particles injected onto the first region.

16. The method of claim 11, further comprising after the processing of the surfaces of the first region and the second region, installing the substrate supporting apparatus inside a chamber.

17. The method of claim 16, wherein
the providing of the mounting part comprises forming an insertion hole in a periphery of the mounting part;
the installing the substrate support apparatus inside a chamber comprises:
installing an engagement member into the insertion groove and making the engagement member engage with a transporting apparatus; and
positioning the substrate supporting apparatus inside the chamber by means of the transporting apparatus.

18. The method of claim 17, wherein the installing the substrate support apparatus inside a chamber comprises:
separating the engagement member from the insertion groove; and
filling the inserting groove.
